(19) United States
(12) Patent Application Publication
(10) Pub. No.: US 2003/0125065 A1
(43) Pub. Date: Jul. 3, 2003

(54) Method and apparatus for generating an output signal

(76) Inventors: Ilan Barak, Kfar Saba (IL); Jaime Hasson, Ganei Tikva (IL); Sharon Malevsky, Tel Aviv (IL)

Correspondence Address: Eitan, Pearl, Latzer & Cohen-Zedek, One Crystal Park, Suite 210, 2011 Crystal Drive, Arlington, VA, 22202-3709, US

(21) Appl. No.: 10/026,677

(22) Filed: Dec. 27, 2001

(51) Int. Cl. H04B 17/00; H03C 1/62; H04B 1/04; H01Q 11/12; H04B 7/00; H04Q 7/20

(52) U.S. Cl. 455/522; 455/67.1; 455/126; 455/115

(57) ABSTRACT

Briefly, in accordance with one embodiment of the invention, a transmitter and a method for generating an output signal according to a first and second outphased signals are provided. The method and transmitter generates the first and the second outphased signals according to amplitude and a phase of an input signal.

### BACKGROUND

Modern wireless communication systems such as cellular communication systems may include base stations and mobile stations. The base station may request the mobile station to transmit a Radio Frequency (RF) signal at a targeted power level. The targeted power level may vary, for example, according to the distance of the mobile station from the base station. The RF transmitter of the mobile station may transmit the RF signal at a power level substantially equivalent to the targeted power level. The output power level of the RF transmitter may vary from high power levels to low power levels. This may affect the efficiency of the RF transmitter. The RF transmitter may have reduced efficiency when transmitting signals at low power levels and increased efficiency when transmitting signals at high power levels. Transmitting signals at low power levels with reduced efficiency may increase the current consumption of the RF transmitter and may reduce the battery lifetime of the mobile station.

Furthermore, a vector summation method may be used to control the output power level and to increase the efficiency when transmitting signals at low power levels. However, the method may increase the efficiency of the RF transmitters on a limited power range.

Thus, there is a continuing need for better ways to provide radio transmitters with an increased efficiency across the transmission power range.

### BRIEF DESCRIPTION OF THE DRAWINGS

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings in which:

FIG. 1 is a block diagram representation of a transmitter in accordance with an embodiment of the present invention;

FIGS. 2 and 3 are graphic illustrations of functions which may be used by embodiments of the present invention;

FIG. 4 is a block diagram of an example of the outphasing generator of FIG. 1 in accordance with an embodiment of the present invention; and

FIGS. 5, 6 and 7 are block diagram representations of a transmitter in accordance with alternative embodiments of the present invention.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

### DETAILED DESCRIPTION

In the following detailed description, numerous specific details are set forth in order to provide a thorough understanding of the invention. However, it will be understood by those skilled in the art that the present invention may be practiced without these specific details. In other instances, well-known methods, procedures, components and circuits have not been described in detail so as not to obscure the present invention.

Some portions of the detailed description which follow are presented in terms of algorithms and symbolic representations of operations on data bits or binary digital signals within a computer memory. These algorithmic descriptions and representations may be the techniques used by those skilled in the data processing arts to convey the substance of their work to others skilled in the art.

Unless specifically stated otherwise, as apparent from the following discussions, it is appreciated that throughout the specification discussions utilizing terms such as “processing,” “computing,” “calculating,” “determining,” or the like, refer to the action and/or processes of a computer or computing system, or similar electronic computing device, that manipulate and/or transform data represented as physical, such as electronic, quantities within the computing system's registers and/or memories into other data similarly represented as physical quantities within the computing system's memories, registers or other such information storage, transmission or display devices.

It should be understood that the present invention may use in variety of applications. Although the present invention is not limited in this respect, the circuits and techniques disclosed herein may be used in many apparatuses such as transmitters of a radio system. Transmitters intended to be included within the scope of the present invention include, by a way of example only, cellular radiotelephone transmitters, two-way radio transmitters, digital system transmitters, analog system transmitters and the like.

Type of cellular radiotelephone transmitters intended to be within the scope of the present invention include, although not limited to, Code Division Multiple Access (CDMA) and wide band CDMA (W-CDMA) cellular radiotelephone transmitters for transmitting spread spectrum signals, Global System for Mobile communication (GSM) cellular radiotelephone transmitters, Time Division Multiple Access (TDMA) transmitters, Extended-TDMA (E-TDMA), General Packet Radio Service (GPRS), Extended GPRS transmitters for transmitting amplitude modulated (AM) and phase modulated signals, and the like.

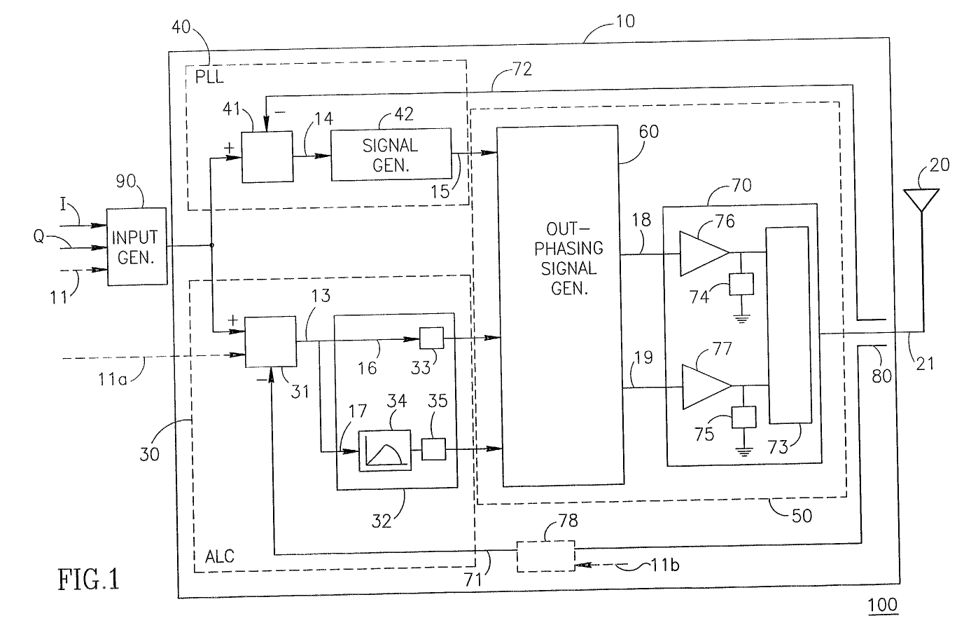

Turning to FIG. 1, an embodiment 100 in accordance with the present invention is described. The embodiment 100 may comprise transmitter 10 such as a radio frequency (RF) transmitter which may be used in base stations, mobile communication device (e.g. cell phone), a two-way radio communication system, avionics systems, government and military radios, radio navigation systems (aircraft, ships, etc.) space based radio systems, radio test equipment (such as channel sounders), cable distribution systems, broadband data radio systems, two way pager, a personal communication system (PCS), or the like. Although it should be understood that the scope and application of the present invention is in no way limited to these examples.

The embodiment 100 may include an antenna 20 that may be used to transmit an output signal 21 (e.g. RF signal). The antenna 20 may be a dipole antenna, a shot antenna, a dual antenna, an omni-directional antenna, a loop antenna or any other antenna type which may be used with mobile station transmitters, if desired. Although the scope of the present invention is not limited to this respect, an average power level of the output signal 21 may be substantially equivalent to a targeted power level 11. The targeted power level 11 may be selected from at least two power levels (e.g. −30 dBm, 0 dBm and 25 dBm). The targeted power level 11 is shown by a dotted line and may be inputted to at least one of alternative inputs across the transmitter 10 block diagram. However, those alternative inputs are an example only, and the present invention is in no way limited to these alternatives. In the embodiments described herein, it should be understood that the output signal 21 (e.g. RF signal) is not intended to be limited to a signal of a particular frequency range, amplitude, or bandwidth. The output signal 21 may be of various frequencies depending, at least in part, on the frequency used in particular wireless communication system. For example, output signal 21 may have a frequency ranging from about 800 MHZ to 950 MHZ, from 1.5 GHZ to 2.5 GHZ, etc. The output signal 21 may be shared by an automatic level control (ALC) loop 30 and a phase lock loop (PLL) 40. The ALC loop 30 and the PLL 40 may generate the output signal 21, and may control the output power level of the output signal 21. Output signal 21 may be described by:

s(t)=\sqrt{P_{T}}a(t)cos(ω₀t+φ(t)) (Eq. 1)

wherein a(t) represents the amplitude modulation of the input signal (I,Q), φ(t) represents the phase modulation of the input signal and ω₀ the carrier frequency, and P_{T} represents the targeted power level.

The ALC loop 30 and the PLL 40 may share, at least in part, an outphasing signal generator 60 and a power amplifier 70. Although the scope of the invention is not limited in this respect, the term “share” and its derivatives may refer to signals and/or components that are included in both PLL 40 and ALC loop 30. Furthermore, shared signals and components may be generated and controlled by both loops concurrently. However, it should be understood to one skilled in the art that in alternative embodiments of the present invention, shared signals and/or components may be shared by other circuits or control loops to serve different purposes and/or the same purpose at the circuits or control loop involving one or more shared signals.

The PLL 30 may generate and control the phase of the output signal 21 and ALC loop 40 may generate and control the amplitude and/or the power level of the output signal 21. The shared components and signals are shown by dotted block 50. Outphasing signal generator 60 may generate two outphased signals 18 and 19 which are shared by the ALC loop 30 and the PLL 40. Power amplifier 70 may include a first power amplifier 76, a second power amplifier 77 and a combiner 73.

The outphasing signal generator 60 may generate at least two outphased signals 18 and 19. Outphased signals 18, 19 may be described by equations 2A and 2B.

$$\begin{matrix}( 18 ) & {s}_{1} ( t ) = \frac{A ( t )}{2} ( cos ( {ω}_{0} ( t ) + φ ( t ) + θ ( t ) ) & \end{matrix} \qquad \text{(Eq. 2A} )$$

$$\begin{matrix}( 19 ) & {s}_{2} ( t ) = \frac{A ( t )}{2} ( cos ( {ω}_{0} ( t ) + φ ( t ) - θ ( t ) ) & \end{matrix} \qquad ( \text{Eq. 2B)}$$

wherein, A(t) and θ(t) are functions of P_{T} and a(t). For example, to generate two constant envelope signals, A(t) and θ(t) may be selected as follows:

$$A ( t ) = k > max ( \sqrt{{P}_{T}} a ( t ) ) and θ ( t ) = {cos}^{- 1} ( \frac{\sqrt{{P}_{T}} a ( t )}{k} ) , and$$

to generate two constant phase signals, A(t) and θ(t) may be selected as follows:

θ(t)=θₖ, 0<θₖ<90°and A(t)=\sqrt{P_{T}}a(t).

Power amplifier 70 may be coupled to the output of outphasing generator 60.

The two outphased signals 18, 19 may be inputted to power amplifier 70. Power amplifier 70 may provide the output signal 21 to the antenna 20. Output signal 21 s(t) may be generated by combining the outphased signal s₁(t) with the outphased signal s₂(t) as in equation 3:

s(t)=s₁(t)+s₂(t) (Eq. 3)

Although the scope of the invention is not limited in this respect, a coupler 80 may be shared by the PLL 40 and the ALC loop 30. The coupler 80 may provide feedback signals 71 and 72 of the ALC loop 30 and the PLL 40. The feedback signals 71 and 72 may be processed from the output signal 21. In an alternative embodiment of the present invention, a converter 78 may be provided. Converter 78 may be shared by the PLL 40 and ALC loop 30. Converter 78 may receive a reduced level of the output signal 21 from the coupler 80. Converter 78 may combine the output signal 21 with the targeted power level 11b and down convert the combined signal into an IF signal. Converter 78 may be adapted to provide feedback signal 71 to amplitude error detector 31. Feedback signal 71 may be described by equation 4:

$${s}_{Fdbck} ( t ) = \frac{\sqrt{{P}_{T}} a ( t )}{K} cos ( {ω}_{IF} t + φ ( t ) ) \qquad \text{(Eq. 4)}$$

wherein

$$\frac{\sqrt{{P}_{T}} a ( t )}{K}$$

may be the reduced output signal.

In another alternative embodiment of the present invention, coupler 80 may provide a feedback signal which may be split between the ALC loop 30 and the PLL 40. For simplicity, the feedback signal is referred hereinafter as two feedback signals 71 and 72, wherein feedback signal 71 is the feedback signal of the ALC loop 30 and feedback signal 72 is the feedback signal of PLL 40.

In this particular embodiment, the ALC loop 30 may further include an amplitude error detector 31 and at least one control signal generator 32. Amplitude error detector 31 may provide an amplitude error signal (e_{A}(t)) 13 according to an input signal 12, feedback signal 71 and targeted power level 11a (shown with a dotted line). Amplitude error detector 31 may include amplitude detectors (not shown), which may detect the amplitude component of input signal 12 and feedback signal 71. Amplitude error detector 31 may further include a “level converter” which may convert the targeted power level 11a to amplitude. Amplitude error signal 13 may be the sum of differences between amplitude of the input signal 12, the targeted power level 11a and the feedback signal 71. It should be understood that this embodiment of the amplitude error detector 31 is an example only and the scope of the present invention is not limited in this respect.

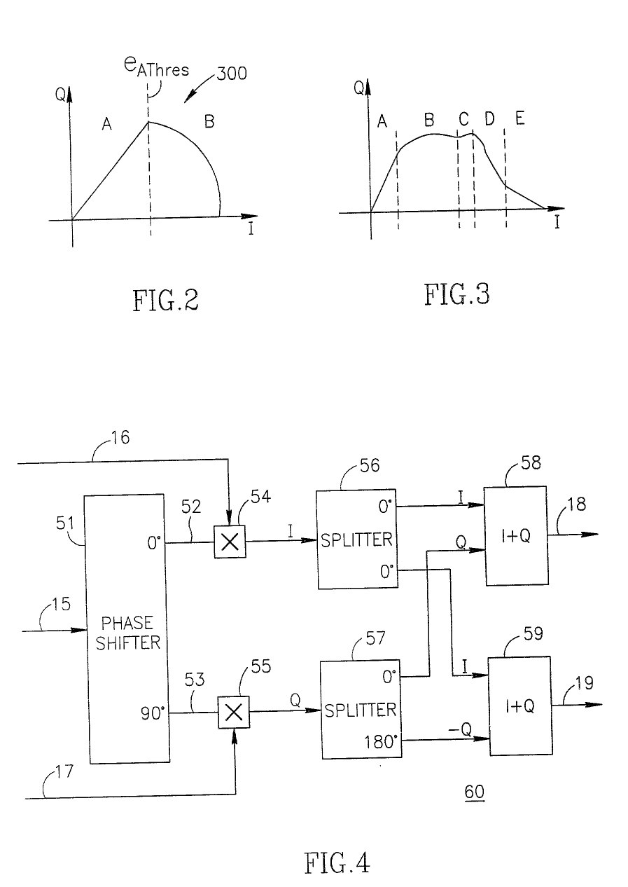

Although the scope of the invention is not limited to in this respect, the ALC loop 30 may further include the control signal generator 32. As shown, control signal generator 32 may be coupled to the output of the amplitude error detector 31 and may be adapted to generate control signals (C_{A1}(t)) 16 and (C_{A2}(t)) 17 according to amplitude error signal 13. The control signal 16 may be determined, at least in part, by the amplitude error signal 13 and may be filtered by filter 33. In an alternative embodiment of the present invention, the amplitude error signal 13 may be the control signal 16, and may be expressed as C_{A1}(t)=e_{A}(t), if desired. Control signal 17 may be determined, at least in part, by an adaptive function 300 of amplitude error signal 13. An example of adaptive function 300 is shown with FIG. 2 and with block 34 of FIG. 1. Control signal 17 may be filtered by filter 35

Although the scope of the invention is not limited to this respect, FIG. 2 shows the adaptive function 300 which includes two regions, A and B. e_{AThres} may be the limit between the regions A and B and θₖ=cos⁻¹(2e_{A}_{_{Thres}}/k) may be the phase. Although the scope of the invention is not limited in this respect, for e_{A}(t)>e_{AThres} (region A) two constant envelope signals may be provided by the outphasing signal generator 60 to the power amplifier 70. In this case, control signal 17 may be expressed as

$${C}_{A2} ( t ) = \sqrt{\frac{{k}^{2}}{4} - {( {e}_{A} ( t ) )}^{2} .}$$

For e_{A}(t)>e_{AThres} (region B) two constant phase signals may be provided by outphasing signal generator 60 to the power amplifier 70. In this case, control signal 17 may be expressed as C_{A2}(t)=e_{A}(t)cos(θₖ). The above description may be shown by equation 5 below.

$${C}_{A2} ( t ) = \{ \frac{{e}_{A} ( t ) cos ( {θ}_{k} ) }{\sqrt{\frac{{k}^{2}}{4} - {{e}_{A} ( t )}^{2}}} \begin{matrix}{e}_{A} ( t ) < {e}_{{A}_{Thres}} \\ {e}_{A} ( t ) > {e}_{{A}_{Thres}}\end{matrix} \qquad \text{(Eq. 5)}$$

FIG. 3 shows a graphic representation of another example of an adaptive function. The adaptive function of FIG. 3 may include 5 regions. However, any adaptive function may be used by control signal generator 32. Adaptive function 300 may be used for compensating the non-linearity encountered in the power amplifier 70.

Although the scope of the invention is not limited in this respect, adaptive function 300 of control signal 17 may be used to vary the amplitude of the two outphased signals 18 and 19 at a first range of the amplitude error signal 13 to provide increased efficiency of the power amplifier 70. In addition, adaptive function 300 may be used to vary a phase difference of the two outphased signals 18 and 19 at a second range of the amplitude error signal 13 to provide increase efficiency to the power amplifier 70. Although the scope of the invention is not limited in this respect, the adaptive function 300 may be adapted to provide an increased efficiency of the power amplifier at all ranges of power levels of output signal 21.

Although the scope of the invention is not limited in this respect, adaptive function 300 may be adapted continuously in a close loop mode. In alternative embodiment of the invention, the signal C_{A2}(t) may be passed through the filter 35.

Although the scope of the invention is not limited in this respect, PLL 40 may include a phase error detector 41 which is adapted to provide a phase error signal 14 (e_{φ}(t)). Phase error signal 14 may be the phase difference between detected phase of input signal 12 and detected phase of feedback signal 72.

As shown, the PLL 40 may further include a signal generator 42. The phase error detector 41 may receive the phase error signal 14 and may generate an envelope signal 15. Although the scope of the invention is not limited in this respect, envelope signal 15 may be a constant envelope signal and RF signal. In this example, envelope signal will be described as a constant envelope signal. Constant envelope signal 15 may be expressed by equation 6

s_{VCO}_{ₜ}(t)=A_{VCO}cos(ω₀t+φ(t)) (Eq. 6)

wherein A_{VCO} may be a constant, φ(t) may be the desired phase and ω₀ may be the transmitted frequency which may be selected from various frequencies. Furthermore, signal generator 42 may include, for example, a loop filter coupled to a voltage control oscillator (VCO). However, it should be understood that signal generator 42 is not limited to the above example.

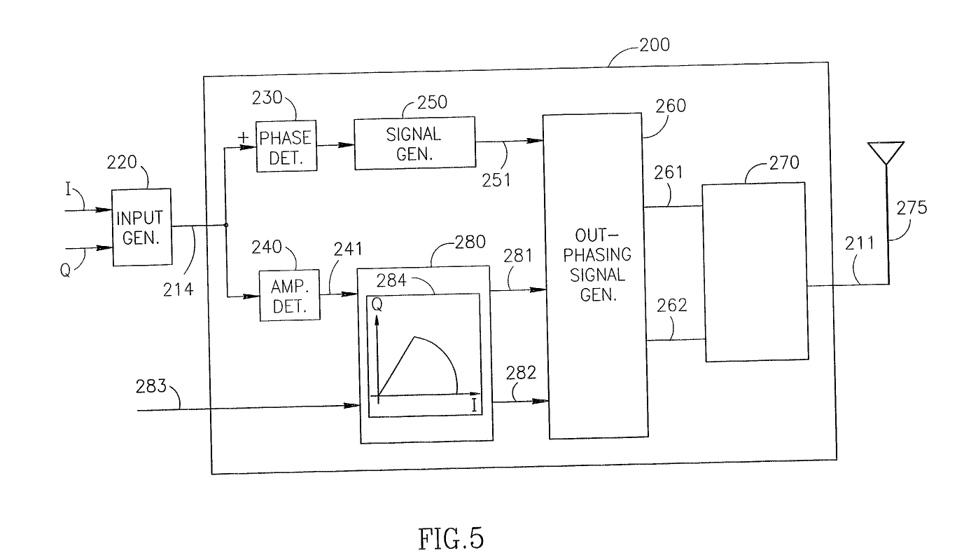

As shown, control signal 16, control signal 17 and constant envelope signal 15 may be coupled to the outphasing generator 60. A detail description of an example of the outphasing signal generator 60 will be given later with reference to FIG. 4.

Control signals 16 and 17 may be adapted to control the instantaneous amplitude of the output signal 21 by varying the amplitude and the phase difference of the outphased signals 18 and 19, according to an amplitude error of the output signal 21. In addition, the constant envelope signal 15 may be adapted to vary the phase of the outphased signals 18, 19 according to the phase error of the output signal 21.

Although the scope of the invention is not limited to this respect, it should be understood to one skilled in the art that the instantaneous amplitude may be the momentary amplitude level of a signal and that level may be different from measurement to measurement of the signal.

As described above, this particular embodiment may include power amplifier 70. As shown, power amplifier 70 may be coupled to the outphasing generator 60. Although the scope of the invention is not limited in this respect, power amplifier 70 may include two power amplifiers 76 and 77 which may be coupled to a combiner 73. Combiner 73 may include two reactive terminations 74 and 75 that may be coupled to amplifiers 76, 77, respectively. As shown, amplifier 76 may be adapted to amplify outphased signal 18 and amplifier 77 may amplify the outphased signal 19. Combiner 73 may combine the two amplified outphased signals to provide the output signal 21.

The particular embodiment may also include an input signal generator (ISG) 90. ISG 90 may receive baseband signals I and Q and may provide the input signal 12 to amplitude error detector 31 and to phase error detector 41. Alternatively, targeted power level signal 11 may be inputted to ISG 90 and may be included in input signal 12.

Input signal 12 may be given by equation 7.

$${s}_{IN} ( t ) = \sqrt{{P}_{T} \cdot ( {I ( t )}^{2} + {Q ( t )}^{2}} cos ( {ω}_{IF} t + arctan ( \frac{Q ( t )}{I ( t )} ) ) \qquad \text{(Eq. 7)}$$

wherein \sqrt{P_{T}} may be adapted to be the amplitude of the targeted power signal 11 at the input of the detectors 41 and 31.

It should be understood that transmitter 10 may also includes other components not shown in FIG. 1, such as filters, oscillators, matching circuits, etc., although the scope of the present invention is not limited by the inclusion or exclusion of such components.

Turning to FIG. 4, a block diagram of an example of the outphasing generator 60 of FIG. 1 in accordance with a particular embodiment of the present invention is shown. As shown, the constant envelope signal 15 may be inputted to a 90° phase shifter 51. The 90° phase shifter 51 may be adapted to split the constant envelope signal 15 into two signals 52 and 53 that may have a phase difference of 90° from each other, if desired. The constant envelope signal 52 may be described by equation 8A and constant envelope signal 53 may be described by equation 8B.

$$\begin{matrix}\begin{matrix}( 52 ) & {s}_{{VCO}_{1}} ( t ) = \frac{{A}_{VCO}}{2} cos ( {ω}_{0} t + φ ( t ) )\end{matrix} & \text{(Eq. 8A)} \\ \begin{matrix}( 53 ) & {s}_{{VCO}_{2}} ( t ) = \frac{{A}_{VCO}}{2} sin ( {ω}_{0} t + φ ( t ) )\end{matrix} & \text{(Eq. 8B)}\end{matrix}$$

For simplicity, the control signal 16 is referred as C_{A1}(t) and the control signal 17 is referred as C_{A2}(t) As shown, a first multiplier 54 may be adapted to multiply C_{A1}(t) with s_{VCO}_{₁}(t) to provide an I signal which may include an amplitude error signal and a phase error signal. Additionally, a multiplier 55 may multiply C_{A2}(t) with s_{VCO}_{₂}(t) to provide a Q signal that may include the amplitude error signal and the phase error signal. The I signal may be inputted to a splitter 56 that may adapted to split the I signal into two I signals. The Q signal may be inputted into a splitter 57 that may split the Q signal into two signals that may have a phase difference of 180°. For simplicity, the splits of Q signal may be referred as “+Q” and “−Q”, if desire. As shown, summer 58 may sum the I signal with +Q signal to provide an I+Q signal. The I+Q signal may also be referred to as outphased signal 18. Additionally, summer 59 may be adapted to sum the I signal with −Q signal to provide an I−Q signal. The I−Q signal may also be referred to as outphased signal 19. The above description of the signal processing may be described by equations 2C and 2D below, wherein outphased signal 18 may be given by:

S₁(t)=C_{A1}(t)·s_{VCO1}(t)+C_{A2}(t)·s_{VCO}_{₂}(t), (Eq. 2C)

and wherein outphased signal 19 may be given by:

s₂(t)=C_{A1}(t)·s_{VCO1}(t)−C_{A2}(t)·s_{VCO}_{₂}(t). (Eq. 2D)

It can be seen that for A_{VCO}=1, equations 2C and 2D are equal to equations 2A and 2B.

Although the scope of the present invention is not limited by this example, it should be understood that other embodiments of the outphasing signal generator may be used.

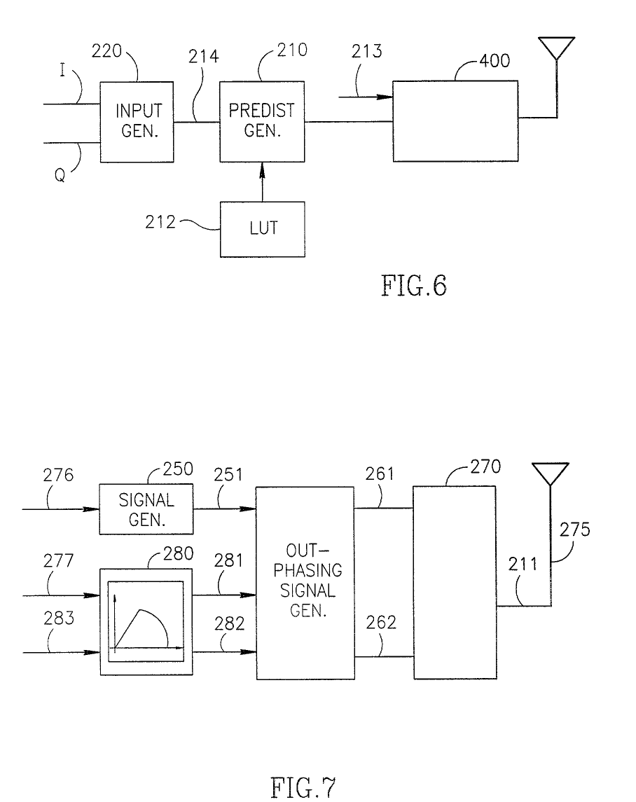

Referring now to FIGS. 5, 6 and 7, block diagrams of a transmitter 200 in accordance with an alternative embodiment of the present invention is provided. One notable difference with this embodiment is that the transmitter 200 may be an open loop transmitter. The transmitter 200 may not include a feedback loop such as a phase lock loop (PLL) and automatic level control (ALC) loop.

FIG. 5 is a block diagram of an open loop transmitter according to an alternative embodiment of the present invention. As shown, an input signal generator 220 may provide an input signal 214 to a phase detector 230 and to an amplitude detector 240. Although the scope of the invention is not limited in this respect, amplitude detector 240 may comprise components which may be adapted to detect amplitude, if desired. The components may be transistors, diodes and the like. As shown, phase detector 230 may be coupled to a signal generator 250. Signal generator 250 may be substantially equal to the signal generator 42 of FIG. 1, for example a phase lock loop (PLL) or a synthesizer. Signal generator 250 may provide a constant envelope signal 251 to outphasing signal generator 260. As shown, control signal generator 280 may generate the control signals (C_{A1}(t)) 281 and (C_{A2}(t)) 282 according to the instantaneous amplitude 241 of the input signal 214.

Although the scope of the invention is not limited to this respect, control signal generator 280 may comprise components such as shift registers, flip-flops, counters, samplers, analog to digital converters, etc. which may be adapted to manipulate the targeted power level 283 with the instantaneous amplitude 241 in accordance with adaptive function 284. Control signal 281 is determined, at least in part, on the instantaneous amplitude 241 which may be C_{A1}(t) A_{IN}(t). Control signal 282 is determined, at least in part, on an adaptive function 284 of the instantaneous amplitude 241. Although, the present embodiment of the invention is not limited to this example, an example of an adaptive function was shown and described with respect to FIG. 2.

As described with FIGS. 1 and 2, the control signal 282 may be

$${C}_{A2} ( t ) = \{ \frac{{A}_{IN} ( t ) cos ( {θ}_{k} ) }{\sqrt{\frac{{k}^{2}}{4} - {{A}_{IN} ( t )}^{2}}} \begin{matrix}{A}_{IN} ( t ) < {A}_{{IN}_{Thres}} \\ {A}_{IN} ( t ) > {A}_{{IN}_{Thres}}\end{matrix} .$$

However, any function which may compensate for the non-linearities encountered in the power amplifier 270 may be used, if desired. As shown, signal generator 250 may be coupled to an outphasing signal generator 260. Outphasing signal generator 260 may be adapted to generate two outphased signals 261 and 262. Outphased signals 261, 262, which have been described above by equations 2A and 2B, may comprise a variable phase, for example, θ(t). Variable phase θ(t) may vary according to the constant envelope signal 251. In addition, outphased signals 261, 262 may comprise variable phase difference cos

$${}^{- 1} ( \frac{a ( t )}{k} )$$

and variable amplitude kcosθ(t)) which may vary according to the control signals 281 and 282. As shown, outphased signals 261, 262 may be coupled to power amplifier 270. Power amplifier 270 may combine the outphased signals 261, 262 to provide an output signal 211 at an average power level to an antenna 275. The average power level may be substantially equal to a targeted power level 283.

An alternative embodiment of the embodiment of FIG. 5 will be described now with reference to FIG. 6. One notable difference with this embodiment is that the input generator 220 is coupled to a predistortion generator 210 which may receive data from a look-up table (LUT) 212. In this respect, the term “predistortion” and its derivatives may refer to manipulation on signals to compensate or cancel distortion of other signals. For example, predistortion of an input signal of a transmitter may compensate or cancel the distortion of an output signal. Predistortion generator 210 may compensate for an error of the output signal 211. The error of the output signal 211 may include distortion, linearity of a power amplifier, etc. Although the scope of the invention is not limited to this respect, LUT 212 may comprise data such as coefficients which the predistortion generator 210 may use to generate the predistorted signal 213. As shown, the predistortion generator 210 may receive an input signal 214 from the input generator 220. The input generator 220 may generate the input signal 214 from baseband signals I and Q. Predistortion generator 210 may be adapted to predistort the input signal according to the coefficients which may be stored at LUT 212 to provide predistorted signal 213. Predistorted signal 213 may be provided to a transmitter 400. In this respect, predistorted signal 213 may be generated according to complementary function of distortion function of the output signal. Thus, predistortion signal 213 may compensate the distortion of the output signal. Although, this embodiment is not limited to this example, targeted power level 283 may be provided to the transmitter 400. Furthermore, transmitter 400 may be the same or similar to the transmitter to of FIG. 1 or may be substantially equal to transmitter 200 of FIG. 5.

Although the scope of the invention is not limited in this respect, another alternative embodiment of the present invention will be describe now with FIG. 7. One notable difference with this embodiment, over the embodiment of FIG. 5, is that the transmitter 200 may be a direct conversion transmitter. Thus, the phase detector 230 and the amplitude detector 240 may not be needed. Although the scope of the invention is not limited in this respect, the transmitter may receive baseband signals which may include a phase of a baseband signal 276 and an amplitude of a baseband signal 277. Baseband signals may be generated at a baseband module (not shown) of the transmitter 400 at a base frequency of the transmitter 400. Baseband signals are not modulated signals thus the phase baseband signal 276 and the amplitude baseband signal 277 may be I and Q signals of an audio signal or a data source. The signal generator 250 may receive the phase 276 and the control signal generator may receive the amplitude 277. The phase may be expressed by

$${φ}_{m} ( t ) = arctan ( \frac{Q ( t )}{I ( t )} )$$

and the amplitude may be expressed by

$${A}_{in} ( t ) = \sqrt{{P}_{l} \cdot ( {I ( t )}^{2} + {Q ( t )}^{2} )} .$$

Although the scope of the invention is not limited in this respect, constant envelope signal 251, outphasing signal generator 260, outphased signals 261, 262, power amplifier 270, output signal 211 and antenna 275 may be substantially equal to constant envelope signal 15, outphasing signal generator 50, outphased signals 18 and 19, power amplifier 60, output signal 21 and antenna 20 of FIG. 1, if desired.

Although the scope of the invention is not limited to this respect, the embodiments of the invention, for example transmitter architecture, are not limited to frequency range and modulation methods. Thus, the transmitter architecture may be used in many communication devices such as cellular radiotelephone mobile devices and base stations, two-way radio systems personal communication systems, personal digital assistants (PDA's), personal communication assistants (PCA) and the like.

While certain features of the invention have been illustrated and described herein, many modifications, substitutions, changes, and equivalents will now occur to those skilled in the art. For example, the use of an adaptive function for varying a phase and amplitude of an output signal may be used in many devices other then transmitters. It is, therefore, to be understood that the appended claims are intended to cover all such modifications and changes as fall within the true spirit of the invention.

What is claimed is:

1. A method comprising:
providing first and second outphased signals that are shared by a phase lock loop and an automatic level control loop.

2. A method of claim 1, further comprising:
generating an output signal according to the first and the second outphased signals.

3. The method of claim 2, further comprising:
controlling an instantaneous amplitude of the output signal by varying an amplitude and varying a phase difference of the first and the second outphased signals according to an amplitude error of the output signal; and
varying a phase of the first and the second outphased signals according to a phase error signal of the output signal.

4. The method of claim 3, further comprising:
generating the amplitude error signal and the phase error signal according to an input signal and the output signal,
generating a first control signal of the automatic level control loop according to the amplitude error of the output signal; and
generating a second control signal of the automatic level control loop determined, at least in part, by an adaptive function of the amplitude error signal.

5. The method of claim 4, further comprising:
varying the amplitudes of the first and the second outphased signals with a first range of the amplitude error of the output signal; and
varying the phase difference of the first and the second outphased signals with a second range of the amplitude error of the output signal.

6. The method of claim 5, further comprising:
transmitting the output signal at an average power level which is substantially equivalent to a targeted power level.

7. The method of claim 6, further comprising:
selecting the targeted power level from a first and a second power levels.

8. A method comprising:
controlling an instantaneous amplitude of an output signal by varying a phase difference and an amplitude of first and second outphased signals according to first and second control signals; and
setting a phase to the first and the second outphased signals according to a phase of an envelope signal.

9. The method of claim 8, further comprising:
generating the envelope signal according to a phase of an input signal;
generating the first and the second control signals according to an adaptive function determined, at least in part, on an instantaneous amplitude of the input signal; and
combining the first and the second outphased signals to provide an output signal at an average power level that is substantially equivalent to a targeted power level.

10. The method of claim 9, wherein generating the first and the second control signal comprises:
manipulating the instantaneous amplitude of the input signal with the targeted power level, wherein the targeted power level is selected from first and second power levels.

11. The method of claim 10, comprising:
varying amplitudes of the first and the second outphased signals at a first range of the instantaneous amplitude; and
varying the phase difference of the first and the second outphased signals at a second range of the instantaneous amplitude.

12. A method comprising:
generating first and second control signals according to an adaptive function determined, at least in part, by an instantaneous amplitude of a predistorted signal; and
varying a phase difference and an amplitude of the first and the second outphased signals according to the first and the second control signals.

13. The method of claim 12, further comprising:
generating an envelope signal according to a phase of the predistorted signal; and
varying a phase of the first and the second outphased signals according to the envelope signal.

14. The method of claim 12, further comprising;
combining the first and the second outphased signals to provide an output signal at an average power level which is substantially equivalent to a targeted power level; and
generating the predistorted signal to compensate for distortion at the output signal.

15. The method of claim 14, wherein generating the first and the second control signal comprises:
manipulating the instantaneous amplitude of the input signal with the targeted power level, wherein the targeted power level is selected from first and second power levels.

16. An apparatus comprising:
a coupler to provide a feedback signal of an output signal to a phase lock loop and an automatic level control loop;
an outphased signal generator and a power amplifier that are shared by the phase lock loop and the automatic level control loop; and
a dipole antenna to transmit the output signal according to a targeted power level.

17. The apparatus of claim 16, wherein the phase lock loop further comprises:
a phase error detector which is adapted to provide a phase error signal according to an input signal and the output signal; and
a signal generator to generate a envelope signal according to the phase error signal.

18. The apparatus of claim 17, wherein the automatic level control loop comprises:
an amplitude error detector to provide an amplitude error signal according to the input signal and the output signal; and
a control signal generator to generate first and second control signals according to the amplitude error signal, wherein the first control signal is determined, at least in part, by the amplitude error signal and the second control signal is determined, at least in part, by an adaptive function of the amplitude error signal.

19. The apparatus of claim 18, wherein the second control signal are adapted to vary amplitudes of the first and the second outphased signals at a first range of the amplitude error signal and to vary a phase difference of the first and the second outphased signals at a second range of the amplitude error signal.

20. The apparatus of claim 16, wherein the power amplifier further comprises:
first and second power amplifiers which are adapted to amplify the first and the second outphased signals; and
a combiner which is adapted to combine the first and the second amplified outphased signals.

21. The apparatus of claim 20 wherein the targeted power level is to be selected from first and second power levels.

22. An apparatus comprising:
a control signal generator to generate first and second control signals according to an adaptive function determined, at least in part, by an instantaneous amplitude of an input signal; and
an outphasing signal generator to generate first and second outphased signals according to the first and the second control signals and a constant envelope signal.

23. The apparatus of claim 22, further comprising:
a power amplifier to provide an output signal according to the first and the second outphased signals and to transmit the output signal at an average power level which is substantially equivalent to a targeted power level.

24. The apparatus of claim 23, wherein the first and the second control signals are adapted to vary amplitudes of the first and the second outphased signals at a first range of the instantaneous amplitude and to vary a phase difference of the first and the second outphased signals at a second range of the instantaneous amplitude.

25. The apparatus of claim 24, wherein the control signal generator is further adapted to manipulate the instantaneous amplitude of the input signal with the targeted power level, wherein the targeted power level is selected from first and second power levels.

26. An apparatus comprising:
a signal generator which is adapted to generate an envelope signal according to a phase of a baseband signal;
a control signal generator to generate first and second control signals according to an adaptive function determined, at least in part, by an instantaneous amplitude of a baseband signal.

27. The apparatus of claim 26 further comprising:
an outphasing signal generator to generate the first and the second outphased signals according to the first and the second control signals and according to the envelope signal, wherein the first and the second outphased signals comprise a phase which is provided by the envelope signal, a variable phase difference and a variable amplitude which varies according to the first and the second control signals.

28. The apparatus of claim 27 further comprising:
a power amplifier which is adapted to provide an output signal according to the first and the second outphased signals at an average power level which is substantially equivalent to a targeted power level.

29. The apparatus of claim 28, wherein the control signal generator is further adapted to manipulate the instantaneous amplitude of the input signal with the targeted power level, wherein the targeted power level is selected from first and second power levels.
